(19) United States
(12) Patent Application Publication
(10) Pub. No.: US 2017/0300039 A1
(43) Pub. Date: Oct. 19, 2017

(54) ELECTRONIC DEVICE AND PROGRAM

(71) Applicant: NIKON CORPORATION, Tokyo (JP)

(72) Inventors: Takeaki SUGIMURA, Yokohama (JP); Genshi YOSHIOKA, Tokyo (JP)

(73) Assignee: NIKON CORPORATION, Tokyo (JP)

(21) Appl. No.: 15/633,261

(22) Filed: Jun. 26, 2017

Related U.S. Application Data
(63) Continuation of application No. PCT/JP2016/058304, filed on Mar. 16, 2016.

(30) Foreign Application Priority Data
Mar. 18, 2015 (JP) 2015-054222

(51) Int. Cl. G05B 19/416; H05K 5/00

(52) U.S. Cl. CPC G05B 19/416; H05K 5/0086; G05B 2219/37435

(57) ABSTRACT

An electronic device includes an acceleration detector configured to detect an acceleration of a housing, a vibration generating part having a plurality of vibrators configured to generate vibrations, and a vibration controller configured to generate a virtual vibration source felt by a user who touches the housing by controlling vibrations of each of the plurality of vibrators, wherein the vibration controller generates the virtual vibration source on the basis of the acceleration detected by the acceleration detector.

### CROSS-REFERENCE TO RELATED APPLICATION

Priority is claimed on Japanese Patent Application No. 2015-054222, filed Mar. 18, 2015. This application is a continuation application of International Patent Application No. PCT/JP2016/058304, filed on Mar. 16, 2016. The contents of the above-mentioned applications are incorporated herein by reference.

### BACKGROUND

The present invention relates to an electronic device and a program.

In the related art, a technology of informing a user of information by generating vibrations is known. For example, an imaging apparatus disclosed in Japanese Unexamined Patent Application, First Publication No. 2011-133684 informs a user of generation of camera shake and a direction thereof by sequentially vibrating some vibration units arranged in the direction of the camera shake among a plurality of vibration units. In addition, Re-publication of PCT International Publication No. WO2004/103244 discloses a technology of detecting a change in posture of a user, and informing the user of the change in posture and the changed direction thereof by selectively vibrating the vibrators arranged substantially parallel to the changed direction in order to apply stimulus to the skin.

### SUMMARY

However, in an informing method in the related art, the method only informs a user of a direction by vibrations, and no further expression by vibrations is considered.

An aspect of the present invention provides an electronic device and a program that are capable of allowing a user to recognize a new expression aspect by vibrations.

An aspect of the present invention provides an electronic device including an acceleration detector configured to detect an acceleration of a housing, a vibration generating part having a plurality of vibrators configured to generate vibrations, and a vibration controller configured to generate a virtual vibration source felt by a user who touches the housing by controlling vibrations of each of the plurality of vibrators, wherein the vibration controller generates the virtual vibration source on the basis of the acceleration detected by the acceleration detector.

In addition, another aspect of the present invention provides a program allowing a computer of an electronic device including an acceleration detector configured to detect an acceleration of a housing and a vibration generating part having a plurality of vibrators that generate vibrations, to function as a vibration controller configured to generate a virtual vibration source felt by a user who touches the housing by controlling the vibrations generated by each of the plurality of vibrators on the basis of the acceleration detected by the acceleration detector.

### BRIEF DESCRIPTION OF THE DRAWINGS

FIG. 1 is a schematic diagram showing an example of an exterior configuration of an electronic device according to an embodiment of the present invention.

FIG. 2 is a configuration view showing an example of a functional configuration of the electronic device according to the embodiment of the present invention.

FIG. 3 is a partially transparent view exemplarily showing arranged positions of vibrators included in a vibration generating part according to the embodiment of the present invention.

FIG. 4 is a view exemplarily showing shearing stress data included in localization data stored in a storage according to the embodiment of the present invention.

FIG. 5 is a schematic diagram showing an example of a vibration localized position controlled by the electronic device according to the embodiment of the present invention.

FIG. 6 is a schematic diagram showing an example of combination of amplitudes of vibrators according to the embodiment of the present invention.

FIG. 7 is a flowchart for describing an operation of a controller according to the embodiment of the present invention.

FIG. 8 is a schematic diagram showing an example of movement of a localized position when the electronic device according to the embodiment of the present invention is moved.

### DESCRIPTION OF EMBODIMENTS

Hereinafter, an embodiment of the present invention will be described with reference to the accompanying drawings.

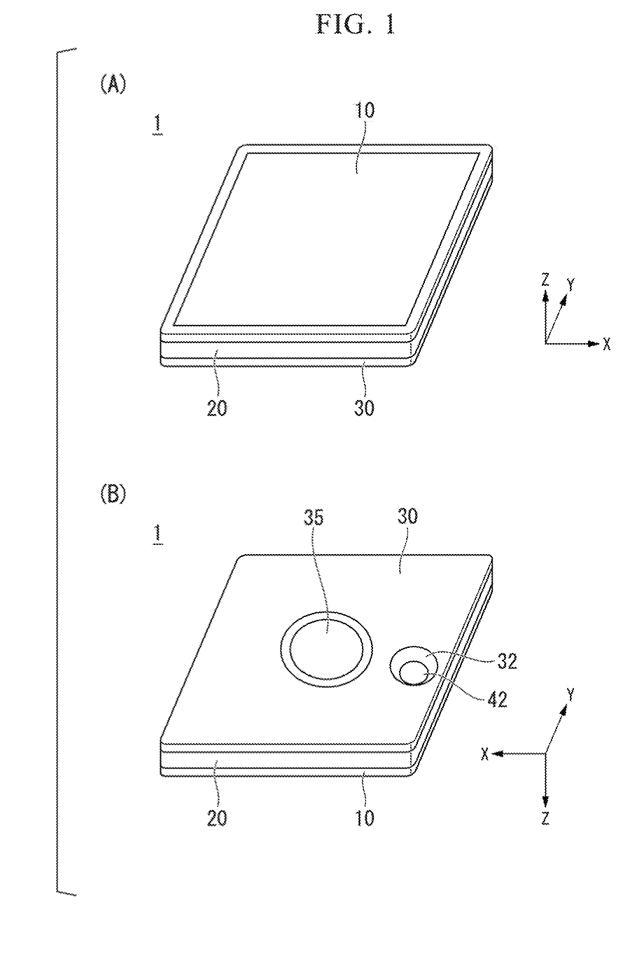

FIG. 1 is a schematic diagram showing an example of an exterior configuration of an electronic device 1 according to the embodiment of the present invention.

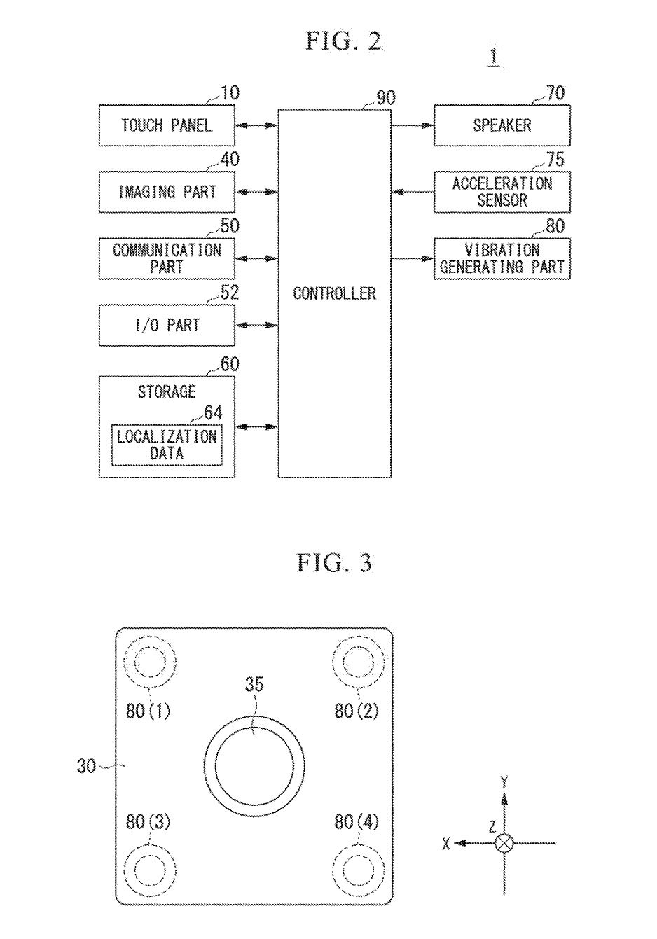

In addition, FIG. 2 is a configuration view showing an example of a functional configuration of the electronic device 1 according to the embodiment.

As shown in FIG. 1, for example, the electronic device 1 has a substantially rectangular shape when seen in a Z direction, and has a configuration in which a touch panel 10, a main body section 20 and a rear cover 30 are stacked in the Z direction. Part (A) of FIG. 1 shows an exterior configuration of the electronic device 1 when seen from the touch panel 10 side. In addition, Part (B) of FIG. 1 shows an exterior configuration of the electronic device when seen from the rear cover 30 side.

Further, a shape of the electronic device 1 shown in FIG. 1 is an example, and it is not limited thereto. For example, the electronic device 1 may be a wearable apparatus having a shape matching a portion of a human body. More specifically, the electronic device 1 may be an apparatus having a helmet shape matching a shape of the head of a human.

Hereinafter, in the embodiment, a configuration of the electronic device 1 will be described using an XYZ orthogonal coordinate system.

In the XYZ orthogonal coordinate system, a stacking direction of components of the electronic device 1 is referred to as the Z direction. In addition, a plane perpendicular to the Z direction is referred to as an XY plane, and directions perpendicular to each other on the XY plane are referred to as an X direction and a Y direction, respectively. The touch panel 10 displays an image input from a controller 90 accommodated in the main body section 20, detects a position (coordinates) on a surface thereof to which a user's finger or the like comes into contact with, and outputs the detected position to the controller 90. Here, the user is a user of the electronic device 1. The touch panel 10 is constituted by, for example, assembling a liquid crystal display device configured to display an image and a contact detection mechanism. Various kinds of contact detection mechanism may be used; for example, contact detection mechanisms of various types such as a resistive membrane type, a capacitive sensing type, an infrared type, a surface acoustic wave type, and so on, may be employed.

In addition, an organic electroluminescence (EL) display device or the like may be used as the touch panel 10, instead of a liquid crystal display (LCD).

The main body section 20 accommodates an imaging part (a camera) 40, a communication part 50, an I/O (I/O port, I/O interface) part 52, a storage 60, a speaker 70, an acceleration sensor 75, a vibration generating part 80, the controller 90, and so on, which are shown in FIG. 2, in a housing. In addition, the main body section 20 may accommodate a power supply circuit or a battery, a global positioning system (GPS) receiver, and so on, in the housing. A hole section 32 is formed in the rear cover 30 to expose a lens 42 of the imaging part 40. In addition, a mounting section 35 on which various operation switches such as a release button or the like configured to operate the imaging part 40 are mounted is attached to the rear cover 30.

The imaging part 40 is a digital camera using a solid state imaging element such as a charge coupled device (CCD), a complementary metal oxide semiconductor (CMOS), or the like. Further, the imaging part 40 may be a video camera.

The communication part 50 performs wireless communication using a wireless LAN network such as Wi-Fi (Registered Trademark) or the like, Bluetooth (Registered Trademark), infrared communication, a mobile phone network, a PHS network, and so on.

In addition, the communication part 50 may include a network card or the like that functions as a communication interface when the electronic device is wired-connected. The I/O part 52 includes, for example, a universal serial bus (USB) terminal, a high definition multimedia interface (HDMI, Registered Trademark) terminal, a terminal on which an SD card or the like is mounted, or the like.

The speaker 70 outputs audio on the basis of audio data generated by the controller 90.

The acceleration sensor 75 (the acceleration detector) is, for example, a three-axis type acceleration sensor. The acceleration sensor 75 (the acceleration detector) detects accelerations (including a gravitational acceleration) applied to the housing of the electronic device 1 in the X direction, the Y direction and the Z direction, and outputs a detection result to the controller 90.

Further, the electronic device 1 may not include the imaging part 40, the communication part 50, the I/O part 52 and the speaker 70 as long as detection of an acceleration and generation of vibrations are possible.

The vibration generating part 80 generates vibrations on the basis of a driving signal generated by the controller 90. The vibration generating part 80 includes a plurality of vibrators as shown in FIG. 3.

FIG. 3 is a partially transparent view exemplarily showing arranged positions of the vibrators included in the vibration generating part 80 of the embodiment. Specifically, as shown in FIG. 3, the vibration generating part 80 includes, for example, vibrators 80(1), 80(2), 80(3) and 80(4) disposed in the vicinity of four corners of the electronic device 1. The vibrators are attached to a housing or a support member of the main body section 20, the rear cover 30, or the like. For example, a voice coil motor (VCM), an eccentric motor, or the like, is used as the vibrator. When the voice coil motor is used, the vibrator generates, for example, vibrations in the Z direction with respect to a portion or the entirety of the electronic device 1.

Further, the disposition of the vibrators is not limited to that shown in FIG. 3 and other dispositions may be provided. For example, the vibration generating part 80 may include vibrators in the vicinity of two corners disposed diagonally opposite each other in the electronic device 1 or may include vibrators at the other positions. In addition, the number of the vibrators is not limited to four as shown in FIG. 3 and two vibrators or more may be provided. An aspect of the vibrations generated by the vibration generating part 80 may be changed by changing elements such as an amplitude, a frequency, a phase, a duty, or the like.

The controller 90 performs control of the entire electronic device 1 including the vibration generating part 80. The controller 90 includes a vibration controller (not shown) serving as a functional unit. The vibration controller controls vibrations of the vibration generating part 80 by outputting a vibration signal to the vibration generating part 80. The vibration controller generates a virtual vibration source felt by a user who touches the housing of the electronic device 1 by controlling vibrations of the vibration generating part 80 in this way. Further, in the following description, control performed by the vibration controller will be described as control controlled by the controller 90.

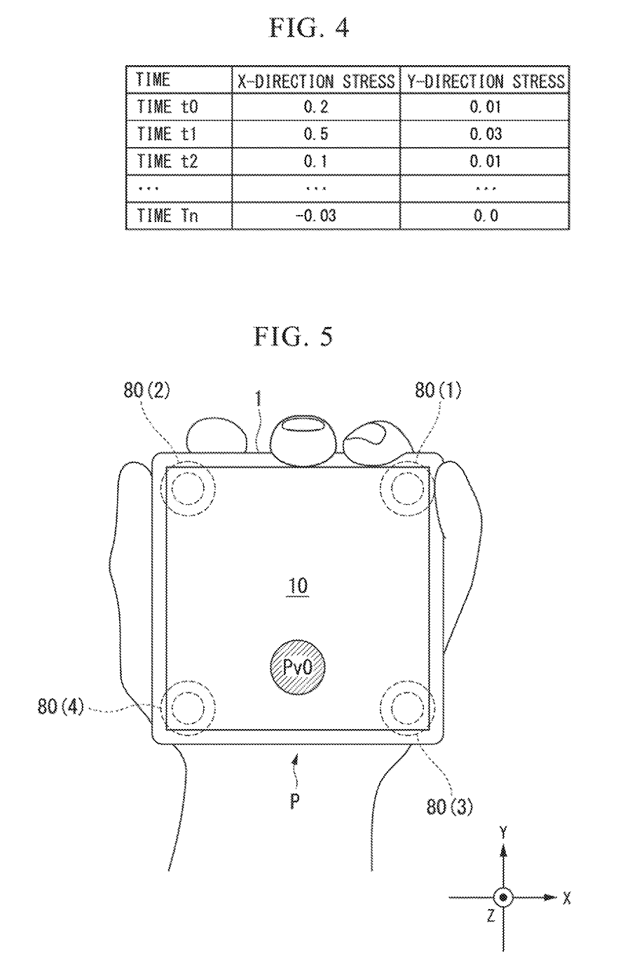

The storage 60 is a storage device such as a flash memory, a hard disk drive (HDD), a random access memory (RAM), a read only memory (ROM), a register, or the like. A program (firmware) executed by a central processing unit (CPU) of the controller 90 is previously stored in the storage 60. In addition, an arithmetic operation result obtained by arithmetic operation processing of the CPU is stored in the storage 60. In addition, contents data received from another apparatus via the communication part 50, contents data read from a device mounted on the I/O part 52, and so on, are stored in the storage 60. In addition, in addition to image data 62 serving as original data of images displayed on the touch panel 10, for example, localization data 64 corresponding to the image data 62 is stored in the storage 60 as information for allowing, for example, the controller 90 to control the vibration generating part 80. The localization data 64 will be described with reference to FIG. 4.

FIG. 4 is a view exemplarily showing shearing stress data included in the localization data 64 stored in the storage 60 of the embodiment. The localization data 64 includes an acceleration measured at each time points and a shearing stress measured at each time points by a measuring device including, for example, an acceleration sensor, a shearing stress sensor and a cavity portion. The shearing stress sensor is a sensor on a flat plate installed on a lower surface or an upper surface of the housing of the measuring device, and measures a force applied to the sensor by a frictional force, i.e., a force in a direction (the X direction and the Y direction) along the lower surface or the upper surface of the housing. For example, the shearing stress sensor periodically measures a shearing stress in the X direction (the X direction stress) and a shearing stress in the Y direction (the Y direction stress), and the localization data 64 includes the X direction stress and the Y direction stress in each of time periods (time points). Further, since the shearing stress sensor is installed on the lower surface or the upper surface, a force counteracting the weight of the measuring device is not measured.

When a liquid such as water, oil, or the like, is put into a cavity portion of the measuring device and the measuring device is moved in a direction along an outer surface of the housing while a portion of the shearing stress sensor is held, the shearing stress is measured as a force applied to the measuring device in order to move the liquid put into the cavity portion. Here, shearing stress is also influenced by such as the fluctuating liquid or the liquid hitting one wall of the cavity portion. A weight may be connected to the housing of the measuring device via a damper or a spring without putting the liquid into the cavity portion of the measuring device.

Further, as a result obtained by applying the force to the measuring device, an acceleration when the measuring device starts to move is measured. Further, while the acceleration sensor measures the acceleration including the gravitational acceleration, in the embodiment, the acceleration of the localization data 64 is a value obtained by removing the gravitational acceleration component from the acceleration measured by the acceleration sensor.

In an example shown in FIG. 4, shearing stress at respective time points is represented as “0.2” in the X direction and “0.01” in the Y direction at a time t0, “0.5” in the X direction and “0.03” in the Y direction at a time t1, . . . , and “−0.03” in the X direction and “0.0” in the Y direction at a time tN.

The controller 90 determines a vibration localized position of the vibrations generated by the vibration generating part 80 and controls the vibrators of the vibration generating part 80 such that the determined vibration localized position is realized with reference to the shearing stress data and the acceleration measured at each time points.

Here, the vibration localized position is a position at which it is intended to make a user feel that vibrations are generated in a state in which the electronic device 1 is held by a palm P of the user. In other words, the vibration localized position is a position recognized as a virtual vibration source in which vibrations are generated by the user who holds the electronic device 1. In the following description, the vibration localized position is also referred as a localized position of the vibrations. The controller 90 controls the vibration localized position on the basis of the localization data 64. Further, in the following description, controlling the vibration localized position is also referred as localizing the vibrations. Here, controlling of the vibration localized position means to perform a control so as to localize a vibration to a coordinate which is in a space in which it is intended to make the user feel that the vibration is generated, by controlling the vibration aspects of each vibrators with the controller 90. Next, a mechanism how the controller 90 localizes the vibrations on the basis of the localization data will be described.

### [Control of Vibration Localized Position]

FIG. 5 is a schematic diagram showing an example of a vibration localized position controlled by the electronic device 1 of the embodiment. In FIG. 5, a position Pv0 is a position it is intended to make the user to feel that vibration is generated in a state in which the electronic device 1 is held by the palm P of the user while the touch panel 10 is directed upward. The controller 90 can make the user to feel that vibrations are generated at the position Pv0 by performing a control of the vibration localized position. An effect of making the user to feel like vibration is generated at a position at which no vibrator is actually disposed is referred to as a localization feeling. The localization feeling is a phantom sensation, that is, when two or more positions on the user's skin are simultaneously vibrated (stimulated), it is a feeling of the user such that it actually feels like the localization of the vibration is localized at a specific position between the two or more positions.

The controller 90, for example, vibrates the vibrators 80(1) to 80(4) such that a position of a center of gravity, obtained by weighting the positions of the vibrators 80(1) to 80(4) by an intensity of the vibrations, coincides with the position Pv0. The intensity of the vibrations is an amplitude, a frequency, or the like, or a combination thereof, and hereinafter, it is assumed as the amplitude. In addition, since the vibrators are attached to, for example, the rear cover 30, as the electronic device 1 is held by the palm P of the user in a state shown in FIG. 5, the vibrations can be easily transmitted to the palm P of the user.

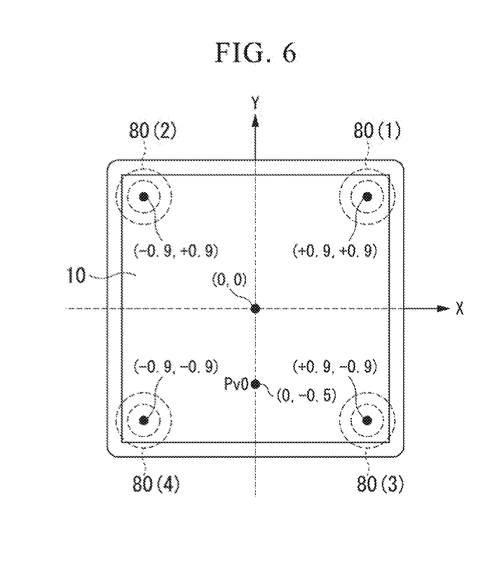

FIG. 6 is a schematic diagram showing an example of a combination of amplitudes of the vibrator of the embodiment. In FIG. 6, a combination of amplitudes of the vibrators 80(1) to 80(4) in which a center of gravity weighted with the amplitude coincides with the position Pv0 is exemplarily shown. In FIG. 6, an intersection of a centerline of the electronic device 1 in the XY direction is defined as an origin of the XY plane. Then, coordinate of the vibrator 80(1) is set as (x, y)=(+0.9, +0.9), coordinate of the vibrator 80(2) is set as (x, y)=(−0.9, +0.9), coordinate of the vibrator 80(3) is set as (x, y)=(+0.9, −0.9), coordinate of the vibrator 80(4) is set as (x, y)=(−0.9, −0.9), and coordinate of the position Pv0 is set as (x, y)=(0, −0.5). Here, the amplitude when the vibrator is not vibrated is 0 (zero)×K, and the amplitude of the maximum vibration that can be generated maximally by the vibrator is 1×K.

K is a standard amplitude. In this case, the controller 90 can allow the user who holds the electronic device 1 in a state of FIG. 5 to feel that the vibration source is present in the vicinity of the position Pv0 by, for example, vibrating the vibrator 80(1) with the amplitude of 0.45×K, vibrating the vibrator 80(3) with the amplitude of 0.55×K and vibrating the vibrator 80(4) with the amplitude of 1×K. Further, in the setting, the vibrator 80(2) is not vibrated (the amplitude of 0×K).

That is, as expressed in the following Equations (1) and (2), as vibrations of the X direction component and vibrations of the Y direction component of the vibrations from the vibrator 80(1) to the vibrator 80(4) are added and subtracted with each other, it is possible to make the user to feel like the vibration is generated in the vicinity of the coordinates (x, y)=(0, −0.5) of the position Pv0. The X direction component of the position Pv0 can be obtained by Equation (1) on the basis of the vibrations of the X direction components of the vibrator 80(1) to the vibrator 80(4). The Y direction component of the position Pv0 can be obtained by Equation (2) on the basis of the vibrations of the Y direction components of the vibrator 80(1) to the vibrator 80(4).

[Math. 1]

{+0.9×0.45×K+0.9×0.55×K−0.9×1×K}/(0.45+0.55+1)K=0 Equation (1)

[Math. 2]

{+0.9×0.45×K−0.9×0.55×K−0.9×1×K}/(0.45+0.55+1)K≈0.5 Equation (2)

In the above-mentioned Equation (1), a term contributed by the vibrator 80(1) is (+0.9×0.45×K), a term contributed by the vibrator 80(3) is (+0.9×0.55×K) and a term contributed by the vibrator 80(4) is (−0.9×1×K).

In the above-mentioned Equation (2), a term contributed by the vibrator 80(1) is (+0.9×0.45×K), a term contributed by the vibrator 80(3) is (−0.9×0.55×K) and a term contributed by the vibrator 80(4) is (−0.9×1×K).

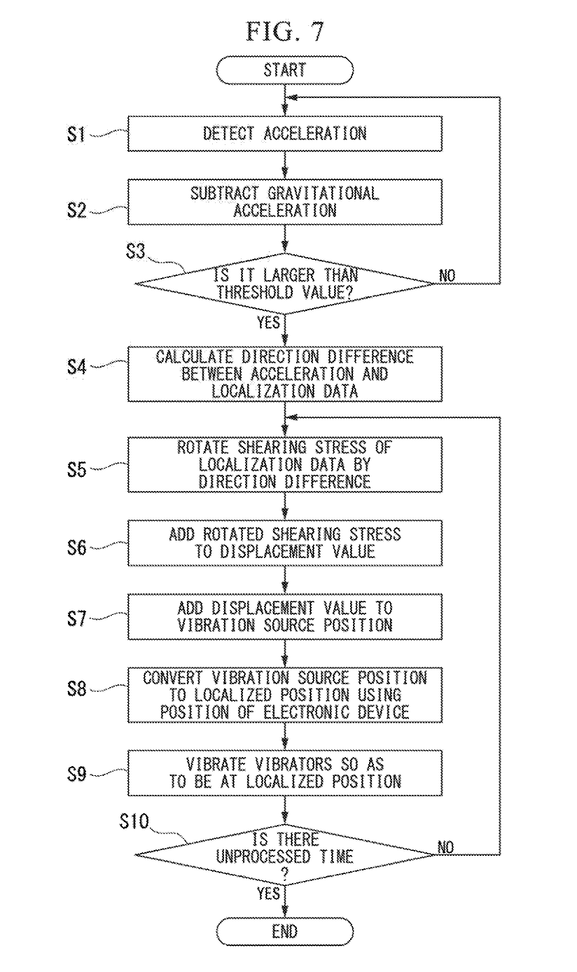

FIG. 7 is a flowchart for describing an operation of the controller 90. The controller 90 first detects an acceleration using the acceleration sensor 75 (S1). Next, the controller 90 subtracts a gravitational acceleration from the acceleration detected by the acceleration sensor 75 (S2). Further, a direction of the gravitational acceleration may be estimated from a detection value of the previous acceleration sensor 75, and may be estimated by detecting rotation of a posture of the electronic device 1 using a gyro sensor or the like (not shown). The controller 90 repeats steps S1 and S2 until a magnitude of the acceleration of the subtraction result in step S2 is a preset threshold value or more (S3).

When the magnitude of the acceleration of the subtraction result in step S2 is the preset threshold value or more (S3—Yes), the controller 90 calculates a deflection difference between the acceleration of the subtraction result in step S2 and the acceleration of the localization data 64 (S4). Further, the direction difference is expressed as a rotation angle around each of the axis of an acceleration vector of the localization data 64 to an acceleration vector which is the subtraction result in step S2. For example, when the acceleration vector of the localization data 64 is (0, 1, 0) and the acceleration vector of the subtraction result in step S2 is (0, 0, 1), the direction difference around the X-axis is 90°, the direction difference around the Y-axis is 0°, and the direction difference around the Z-axis is 0°.

Next, the controller 90 rotates a first shearing stress, among an unprocessed time period of the localization data 64, by the direction difference calculated in step S4 (S5). Next, the controller 90 adds the rotated shearing stress to the displacement value (S6). Further, an initial value of the displacement value is (0, 0, 0). Since the displacement value is the sum of the shearing stress at each time points, the displacement value corresponds to an integrated value of the shearing stress, i.e., a velocity vector of a center of gravity of the liquid in the measuring device.

Next, the controller 90 adds the displacement value calculated in step S6 to a vibration source position (S7). Further, an initial value of the vibration source position is (0, 0, 0). Since the vibration source position is the sum of the displacement value at each time points, the vibration source position corresponds to an integrated value of the displacement value, i.e., a position in a world coordinate system of a center of gravity of the liquid in the measuring device.

Next, the controller 90 calculates a position of the electronic device 1 by second-order-integrating the acceleration detected by the acceleration sensor 75. The controller 90 converts the vibration source position calculated in step S7 into a position (a localized position) in a coordinate system using the electronic device 1 as a reference with reference to the position of the electronic device (S8). The controller 90 vibrates the vibration generating part 80 to create the localized position obtained in step S8 (S9). When unprocessed time is not present in the localization data 64 (S10—No), the processing is terminated, and when unprocessed time is present (S10—Yes), the processing returns to step S5.

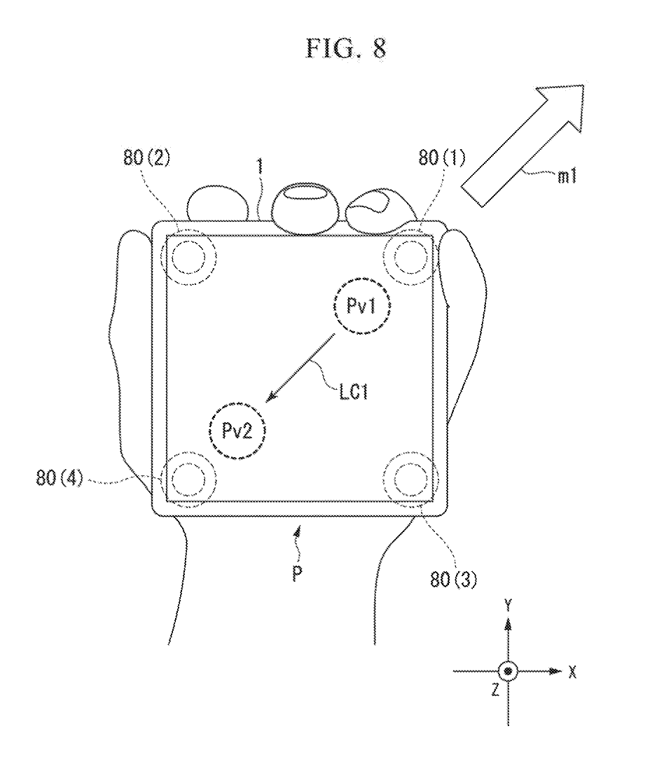

FIG. 8 is a schematic diagram showing an example of movement of the localized position when the electronic device 1 is moved. The example of FIG. 8 is an example of a case in which a user abruptly moves the electronic device 1 in a direction of an arrow ml from a state in which the touch panel 10 of the electronic device 1 is held by the palm P while the touch panel 10 is directed upward. Here, the localized position using the electronic device 1 as a reference is moved from Pv1 to Pv2, i.e., toward LC1 in a direction substantially opposite to the arrow ml. However, in the world coordinate system, Pv2 is substantially a position to which Pv1 is moved in the direction of the arrow ml. For this reason, when a user moves the electronic device 1 in the direction of the arrow ml, the user feels like that some object inside the electronic device 1 has moved in the direction of the arrow ml later than for the electronic device 1. As shown in FIG. 7, the controller 90 determines a moving direction of the localized position on the basis of the direction of the acceleration detected by the acceleration sensor 75. For example, when the direction in which the user moves the electronic device 1 is different from the direction ml by 90 degrees clockwise, the direction of the acceleration detected by the acceleration sensor 75 is also different from the direction ml by 90 degrees clockwise. For this reason, the moving direction of the localized position is also different from the direction LC1 by 90 degrees clockwise.

Further, the localization data 64 may include a displacement obtained by time-integrating the shearing stress, instead of the shearing stress. In this case, since step S6 of FIG. 7 is unnecessary, throughput in the controller 90 can be reduced. However, the displacement is rotated in step S5.

In addition, in step S4 of FIG. 7, a ratio between the magnitude of the acceleration of the localization data 64 and the acceleration of the subtraction result in step S2 may be calculated, and the ratio may be multiplied by the shearing stress of the localization data 64. Alternatively, the ratio may be multiplied by the amplitude, the frequency, or the like, generated by the vibrator. Accordingly, since a moving velocity of the localized position increases or the energy of the vibrations increases as the electronic device 1 is moved with a larger acceleration, it is possible to make the user to feel the movement of the vibration source more strongly.

In addition, in step S3 of FIG. 7, as a predetermined condition, the magnitude of the acceleration, from which the gravitational acceleration is subtracted, is set as a threshold value or more, however, another condition may be provided. For example, when the localization data is data when the measuring device is abruptly accelerated and then stopped, the predetermined condition may be set that the magnitude of the acceleration, from which the gravitational acceleration is subtracted, becomes a threshold value or more and then has substantially the same magnitude in an opposite direction.

In this way, the electronic device 1 includes the controller 90 configured to determine a position of the vibration source at each time points felt by a user by determining an intensity at each time points of the vibrations generated by the plurality of vibrators with reference to the acceleration.

Accordingly, when the electronic device 1 is moved, it is possible to make the user to feel like a movement of some object inside the electronic device 1.

Further, the controller 90 determines a position of the vibration source at each time points with reference to the direction of the acceleration when the acceleration satisfies the predetermined condition.

Accordingly, when a circumstance that can be represented by the acceleration occurs, it is possible to make the user to feel like a movement of some object in the electronic device 1 according to such circumstance.

Further, the controller 90 may determine the position of the vibration source at each time points with reference to the magnitude of the acceleration in addition to the direction of the acceleration.

Accordingly, movement of some object in the electronic device 1 which is made to be felt by the user can be made to correspond to the magnitude of the acceleration of the electronic device 1.

Further, the controller 90 includes the storage 60 configured to store the localization data 64 representing the position of the vibration source at each time points, and determines the position of the vibration source at each time points by converting the position represented by the localization data 64 with reference to the direction of the acceleration.

Accordingly, it is possible to make the user to feel movement of some object in the electronic device 1 on the basis of measurement previously performed by the measuring device or the like.

In addition, the controller 90 may be realized by recording a program configured to execute a function of the controller 90 in FIG. 2 on a computer-readable recording medium, and reading and executing the program recorded on the recording medium using a computer system. Further, “the computer system” disclosed herein includes an operating system (OS) or a hardware such as peripheral devices, or the like.

In addition, “the computer-readable recording medium” may be a portable medium such as a flexible disk, a magneto-optic disk, a ROM, a CD-ROM, or the like, or a storage device such as a hard disk or the like installed in a computer system. Further, “the computer-readable recording medium” includes a medium configured to dynamically hold a program for a short time like a communication line when a program is transmitted via a communication channel such as a network like the Internet, a telephone line, or the like, or a medium configured to temporarily hold a program for a certain time like a volatile storage in a computer system serving as a server or a client in this case. In addition, the program may be provided to execute some of the above-mentioned functions or may be provided to execute the above-mentioned functions through combination with a program already recorded in the computer system.

Hereinabove, while the embodiment of the present invention has been described in detail with reference to the accompanying drawings, a specific configuration is not limited to the embodiment and various design changes may be made without departing from the scope of the present invention.

What is claimed is:

1. An electronic device comprising:
an acceleration detector configured to detect an acceleration of a housing;
a vibration generating part having a plurality of vibrators configured to generate vibrations; and
a vibration controller configured to generate a virtual vibration source felt by a user who touches the housing by controlling vibrations of each of the plurality of vibrators,
wherein the vibration controller generates the virtual vibration source on the basis of the acceleration detected by the acceleration detector.

2. The electronic device according to claim 1,
wherein the vibration controller determines a moving direction of the virtual vibration source on the basis of a moving direction of the housing calculated from the acceleration detected by the acceleration detector.

3. The electronic device according to claim 2,
wherein the moving direction of the virtual vibration source is a direction opposite to the moving direction of the housing.

4. The electronic device according to claim 1,
wherein the vibration controller controls an intensity of the vibrations of each of the plurality of vibrators on the basis of a magnitude of the acceleration detected by the acceleration detector.

5. The electronic device according to claim 1,
wherein the vibration controller generates the virtual vibration source when the acceleration detected by the acceleration detector is a predetermined threshold value or more.

6. The electronic device according to claim 1, further comprising a storage configured to previously and correspondingly store an acceleration and information that represents a time change of a position of a virtual vibration source,
wherein the vibration controller reads the information that represents the time change of the position of the virtual vibration source corresponding to the acceleration detected by the acceleration detector from the storage, and generates the virtual vibration source on the basis of the read information.

7. A program configured to allow a computer of an electronic device comprising an acceleration detector configured to detect an acceleration of a housing and a vibration generating part having a plurality of vibrators that generate vibrations,
to function as a vibration controller configured to generate a virtual vibration source felt by a user who touches the housing by controlling the vibrations generated by each of the plurality of vibrators on the basis of the acceleration detected by the acceleration detector.
